(19) United States
(12) Patent Application Publication
(10) Pub. No.: US 2007/0298880 A1
(43) Pub. Date: Dec. 27, 2007

(54) Gaming Machine With Universal Reel Display System

(76) Inventor: James M. Rasmussen, Chicago, IL (US)

Correspondence Address: NIXON PEABODY LLP, 161 N CLARK ST., 48TH FLOOR, CHICAGO, IL, 60601-3213, US

(21) Appl. No.: 11/662,153

(22) PCT Filed: Sep. 7, 2005
(86) PCT No.: PCT/US05/32148

§ 371 Date: Mar. 7, 2007

Related U.S. Application Data
(60) Provisional application No. 60/608,730, filed on Sep. 9, 2004.

(51) Int. Cl. A63F 9/24; H05K 13/04

(52) U.S. Cl. 463/31; 29/729

(57) ABSTRACT

A gaming machine for conducting a wagering game includes a modular reel display system, comprising a display unit for revealing a plurality of reels, an information module for communicating information to the player, and a removable pay line module in proximity to the display unit and indicating a number of playable pay lines.

### FIELD OF THE INVENTION

The present invention relates generally to gaming machines and, more specifically, to a gaming machine with a modular universal reel display system.

### BACKGROUND OF THE INVENTION

Gaming machines, such as slot machines, video poker machines and the like, have been a cornerstone of the gaming industry for several years. Generally, the popularity of such machines with players is dependent on the likelihood (or perceived likelihood) of winning money at the machine and the intrinsic entertainment value of the machine relative to other available gaming options. Players also appreciate the reliability of a gaming machine, as do the casino operators. Shrewd operators consequently strive to employ the lost entertaining, exciting, and reliable machines available because such machines attract frequent play and hence increase profitability to the operator.

The display area on a gaming machine is the primary viewing area using a variety of visual and lighting techniques to entertain and stimulate the player. As new gaming themes are introduced, the design and visual appearance always change. The requirements for each theme vary and typically, new components are required. Some of the variants that contribute to the continual variations on each machine are based on game type, presentation, whether the display is mechanical or video, and the visual aides necessary for game play.

Gaming machine manufacturers, attempting to control costs, look to reuse components during the design process. The nature of most gaming machines is the unique presentation that limits this possibility. While common base cabinet, internal components, peripherals, top box enclosures, and other components can be used in the development of a new game; typically, the display area and top box presentations are always unique. In many cases, the design of a display area must be unique in order to accommodate certain aspects of the game theme or game play. For example, a multi-line mechanical reel slot game requires multiple lines on the display area to identify the position of the reels that provide a winning outcome. If this game has a certain theme, it is likely that the pay line display will incorporate colors or a design to accommodate that theme.

Another example is the difference between video and mechanical slot machines. Generally, game manufacturers treat these machines as separate devices, especially in the presentation area. A display on a video gaming machine requires a different set of components for presenting the game than a display on a mechanical gaming machine. Just the inherent design of each of the game display area (video vs. mechanical) on these machines would lend credence to the necessity of developing unique components. Add the element of unique themes and it is easy to understand why each design is likely to possess unique components. This, however, poses a complication when attempting to order, inventory, and use parts. Storage space and higher costs are two of the main complications. The other is design time.

Another issue that occurs during development and deployment of a new gaming machine is the issue of localization or translation. While video gaming machines alter code to present text and numbers in a specified language on the display itself, artwork components, found on the machine (such as those viewed in the display area) must be physically altered by using a different part with the appropriate language. This can be costly if the component is unique.

Ultimately, the issue is cost. The continued development of new themes requiring variations in design and appearance contribute heavily to the cost of a gaming machine. Manufacturing time is also affected when unique parts with longer lead-times are holding up production. Every time a new component is needed to support a new theme, cost is impacted.

To help control costs and assist in the development and presentation of new themes, a universal display area comprising multiple variants to components and supporting a variety of display types would help reduce manufacturing times, eliminate the need for new, unique components, and aide in the development of a new theme by speeding up the design phase.

### SUMMARY OF THE INVENTION

The present invention provides a modular universal reel display system on a gaming machine. The universal reel display system provides common modular components allowing for design standards that make it more cost effective when developing new mechanical reel slot machines and makes development and changes during game conversions quicker, easier, and more predictable.

### BRIEF DESCRIPTION OF THE DRAWINGS

The foregoing and other advantages of the invention will become apparent upon reading the following detailed description and upon reference to the drawings in which:

FIG. 1 is a perspective view of a gaming machine with a multi-functional, universal reel display system in accordance with the present invention

FIG. 2 is a block diagram of a control system suitable for operating the gaming machine;

FIG. 3a and FIG. 3b are exploded perspective views of the multi-functional, universal reel display system for the gaming machine;

FIG. 4 is an exploded perspective view of a main bezel and glass viewing area for the multi-functional, universal reel display system shown in FIGS. 3a and 3b;

FIG. 5 is an exploded perspective view of the main bezel and glass viewing area, a base light panel, and a mounting frame comprising the main viewing components of the multi-functional, universal reel display system as shown in FIGS. 3a and 3b;

FIG. 6 is a perspective view of the main viewing components shown in FIG. 5 and of an artwork access and removal method;

FIG. 7 is a view of multiple pay line components for the multi-functional, universal reel display system shown in FIGS. 3a and 3b;

FIG. 8 is an exploded perspective view of multiple reel light panel inserts for the multi-functional, universal reel display system shown in FIGS. 3a and 3b;

FIG. 9 is a an exploded perspective view of a display component options in a lower-left display area on the multi-functional, universal reel display system shown in FIGS. 3a and 3b;

FIG. 10 is a an exploded perspective view of a display component options in a lower-right display area on the multi-functional, universal reel display system shown in FIGS. 3a and 3b;

FIG. 11 is a an exploded perspective view of “light pipe” pay line display components on a reel display area on the multi-functional, universal reel display system shown in FIGS. 3a and 3b;

FIG. 12 is a an exploded perspective view of light emitting diode (LED) reel illumination and pay line display components on a reel display area on the multi-functional, universal reel display system shown in FIGS. 3a and 3b;

FIG. 13 is a perspective view of a common central display printed circuit board (PCB) for connecting components of the multi-functional, universal reel display system shown in FIGS. 3a and 3b;

FIG. 14 is a perspective and side view of a LED display with bezel and translucent, fixed lettering;

FIG. 15 is a perspective and side view of the base light panel with reel and pay line inserts; and

FIG. 16 is a front view of an example reel display with selected components.

While the invention is susceptible to various modifications and alternative forms, specific embodiments have been shown by way of example in the drawings and will be described in detail herein. However, it should be understood that the invention is not intended to be limited to the particular forms disclosed. Rather, the invention is to cover all modifications, equivalents, and alternatives falling within the spirit and scope of the invention as defined by the appended claims.

### DESCRIPTION OF SPECIFIC EMBODIMENTS

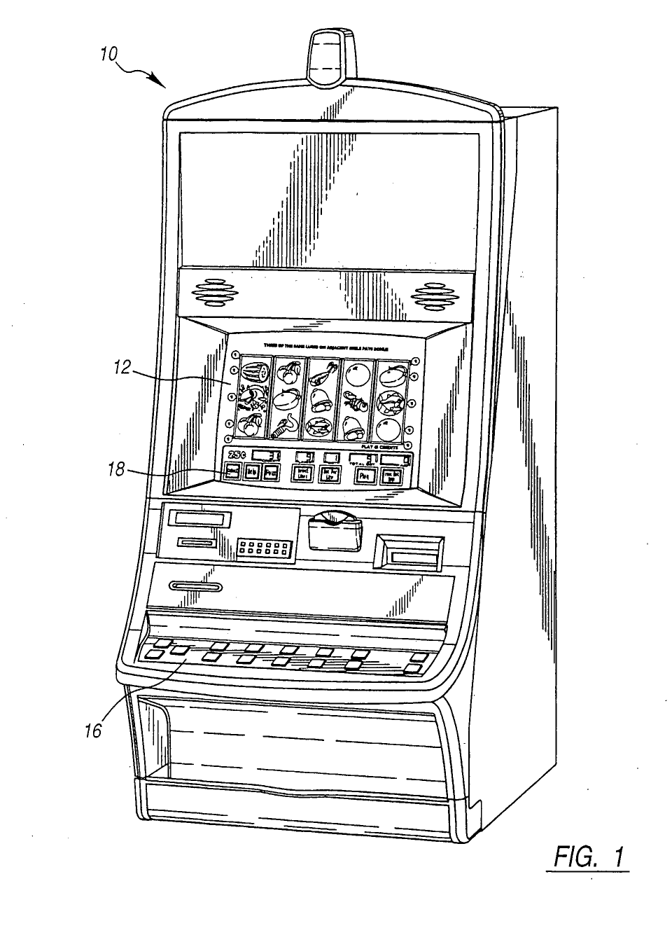

FIG. 1 depicts a gaming machine 10 operable to conduct a slot-based wagering game. In operation, the gaming machine receives a wager from a player to purchase a “play” of the game. In a “play” of the game, the gaming machine generates at least one random event and provides an award to the player for a winning outcome of the random event. The random event may be internally or remotely determined using a random number generator or pooling schema. To portray the random event and outcome to the player, the gaming machine includes a primary display 12. If the wagering game is a reel slot game, for example, the primary display 12 includes a plurality of symbol-bearing reels that are rotated and stopped to place symbols on the reels in visual association with the pay line. The game could also include games such as poker, keno, blackjack, roulette or any other electronic wagering game.

The primary display 12 may be implemented with a CRT, LCD, plasma, mechanical reels (in the case of a reel slot game), or other type of display known in the art. The primary display 12, especially if implemented in video, may be overlaid with a touch screen to facilitate interaction with the player. In the illustrated embodiment, the gaming machine 10 is an “upright” version in which the primary display 12 is oriented vertically relative to the player. Alternatively, the gaming machine may be a “slant-top” version in which the primary display 12 is slanted at about a thirty-degree angle toward the player of the gaming machine 10.

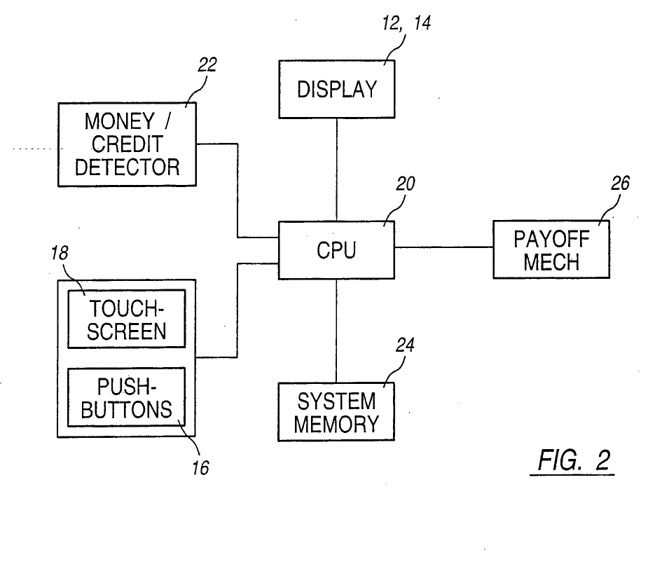

FIG. 2 is a block diagram of a control system suitable for operating the gaming machine. Money/credit detector 22 signals a central processing unit (CPU) 20 when a player has inserted money or played a number of credits. Using a button panel 16 and/or a touch screen 18 (also see FIG. 1), the player may select any variables associated with the wagering game and place his/her wager to purchase a play of the game. In a play of the game, the CPU 20 generates at least one random event using a random number generator (RNG) and provides an award to the player for a winning outcome of the random event. Alternatively, the random event may be generated by a remote computer using an RNG or pooling schema and then transmitted to the gaming machine. The CPU 20 operates the display 12 to represent the random event(s) and outcome(s) in a visual form that can be understood by the player. In addition to the CPU 20, the control system may include one or more additional slave control units for operating the display 12 and any secondary displays.

System memory 24 stores control software, operational instructions and data associated with the gaming machine. In one embodiment, the system memory 24 comprises a separate read-only memory (ROM) and battery-backed random-access memory (RAM). However, it will be appreciated that the system memory 24 may be implemented on any of several alternative types of memory structures or may be implemented on a single memory structure. In fact, the system memory 24 may be located locally or remotely over a network. A payoff mechanism 26 is operable in response to instructions from the CPU 20 to award a payoff to the player. The payoff may, for example, be in the form of a number of credits. The number of credits is determined by one or more math tables stored in the system memory 24.

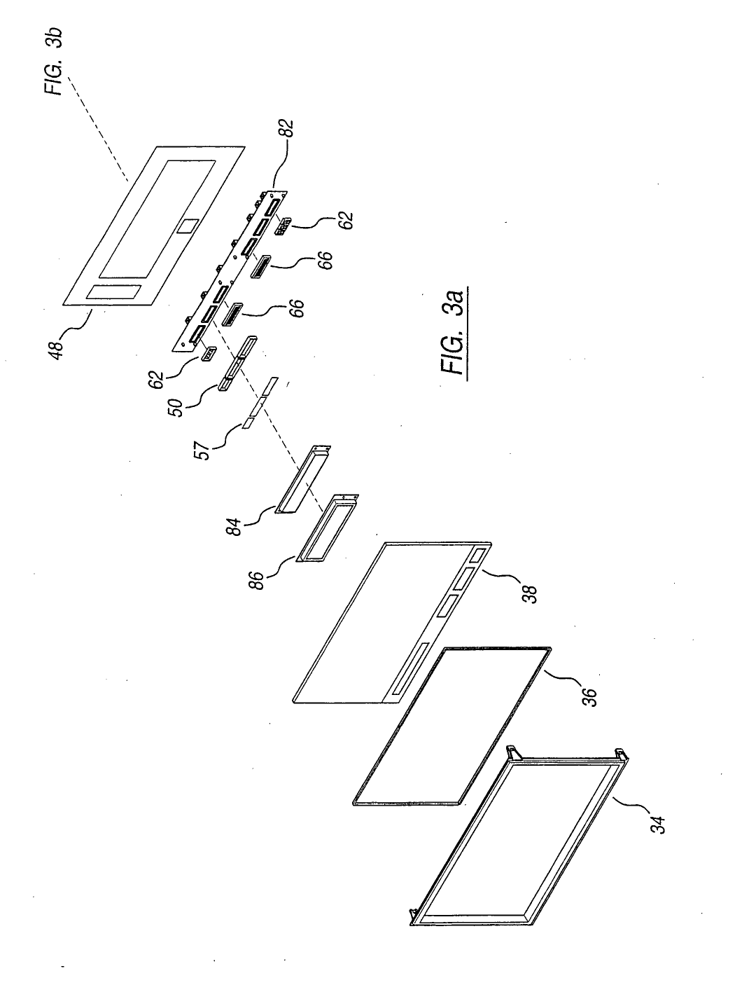

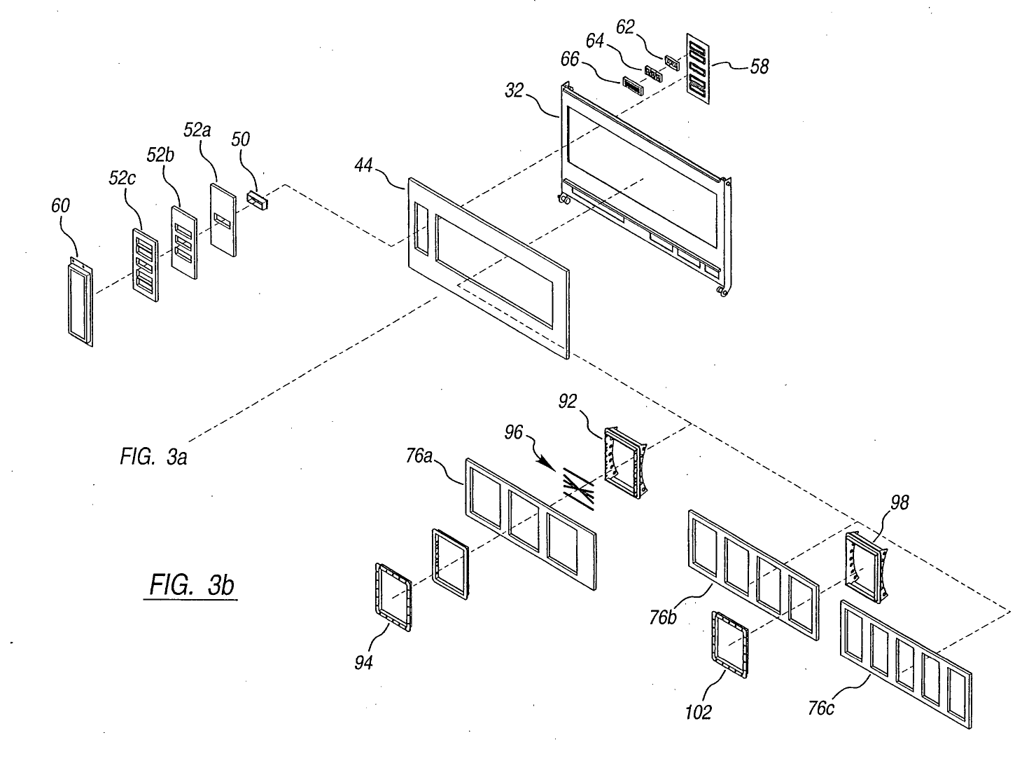

FIGS. 3a-b are exploded perspective views of the multi-functional, universal reel display system for a gaming machine showing a subset of multiple components that can be assembled in many variations depending on the requirements of the game and the design. The primary component, to which other components attach, is the mounting frame 32. A base panel 44 is the primary assembly component for reel and pay line assemblies. Pay line display offerings are all associated with a multi-position printed circuit board (PCB) 58. Varying types of displays can be connected to PCB 58 including LED display 62, 7-segment numeric display 64, and 8-character alphanumeric display 66. A common bezel 50 is used to provide a finished look to a 1-position insert 52a, 3-position insert 52b, or 5-position insert 52c. These light panels are positioned directly within base panel 44. Alternatively, liquid crystal display (LCD) 60 may be used instead of the other presented displays. Reel display openings, of varying numeric opening types are offered to provide choice in design and playability. A 3-position reel insert 76a, a 4-position reel insert 76b, and a 5-position reel insert 76c are presented. Light pipes 96, representing pay lines are connected to a light pipe frame 90 that is positioned within an opening in the 3-position reel light insert 76a. A light pipe bezel 94 completes the assembly. Alternatively, an LED base 98 and LED bezel 102 may be used to display pay lines on reels or reel windows. A variable artwork element 48 provides a simple and cost effective method of displaying thematic visual presentations.

Continuing with FIG. 3-b, a control hub 82 is the primary power and signaling component providing both to the light displays throughout the Universal Reel Display System. Control hub 82 is a printed circuit board (PCB) with all necessary circuitry to provide power and signaling. Light display components such as LED display 62 and 8-character alphanumeric display 66 plug into sockets on the control hub 82. Common bezels 50 and a translucent insert 57 are used to complete the assembly. Alternatively, an LCD 86 with or without a Dotmation screen 88, or a Vacuum Fluorescent Display (VFD) 84, may be used in place of the light displays.

The final components in the Universal Reel Display System are the display bezel 34, the display gasket 36, and the display glass 38. These components comprise the front display assembly 42 that is the surface closest to the player and provide protection from dust and tampering. Front display assembly 42 is a common display assembly for a common slot machine cabinet or for a variety of mechanical reel slot machine designs.

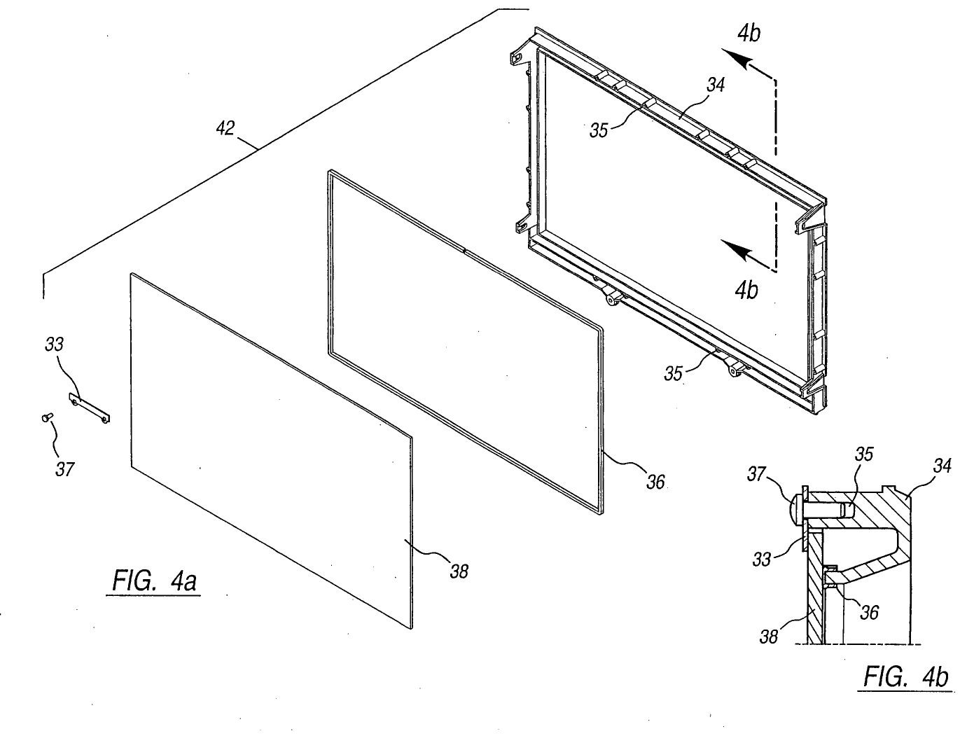

FIG. 4a begins the detailed presentation of the Universal Reel Display System. The front display assembly 42 is comprised of the display bezel 34, the display gasket 36, and the display glass 38. The display bezel 34 is manufactured from a rigid material such as plastic, aluminum, or other metal. The display gasket 36 is a soft rubber compound design with a u-channel to allow for compression between the display bezel 34 and display glass 38 and provide a seal to prevent debris and dust from entering the reel mechanisms. The entire assembly is secured using a bracket 33 and a fastener 37, such as a screw, that connects to the display bezel 34 through fastening holes 35. The fastening holes 35 may be threaded to accept a screw. A sectional view of the top portion of the front display assembly 42 is also presented in FIG. 4b and is taken generally along the line 4b-4b in FIG. 4a. Display bezel 34 is designed to accept display gasket 36 by seating the display gasket's u-channel over and around a frame that is part of the display bezel 34. Display glass 38 is then positioned within the display bezel 34 frame and a bracket 33 is secured to the display bezel 34 with a fastener 37 in fastener hole 35. As can be seen in FIG. 4b, the display glass 38 is secured by pressure from the bracket 33 created when the fastener 37 is tightened to the display bezel 34 via fastener hole 35. As the fastener 37 is tightened, the display glass 38 compresses the display gasket 36 against the display bezel 34, creating a seal. The display glass 38 and the display bezel 34 are manufactured of, or treated with, materials used to dissipate or negate electro-magnetic interference (EMI). The display glass 38 may be treated or coated with EMI shielding material and may or may not have artwork screening. The entire front display assembly 42 is secured to the front of the gaming machine.

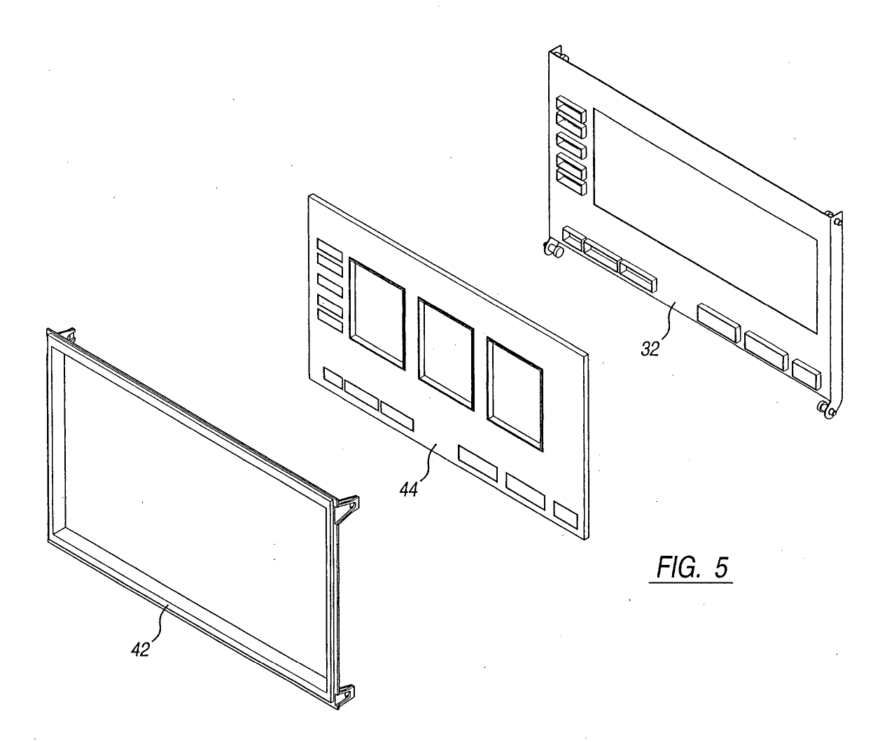

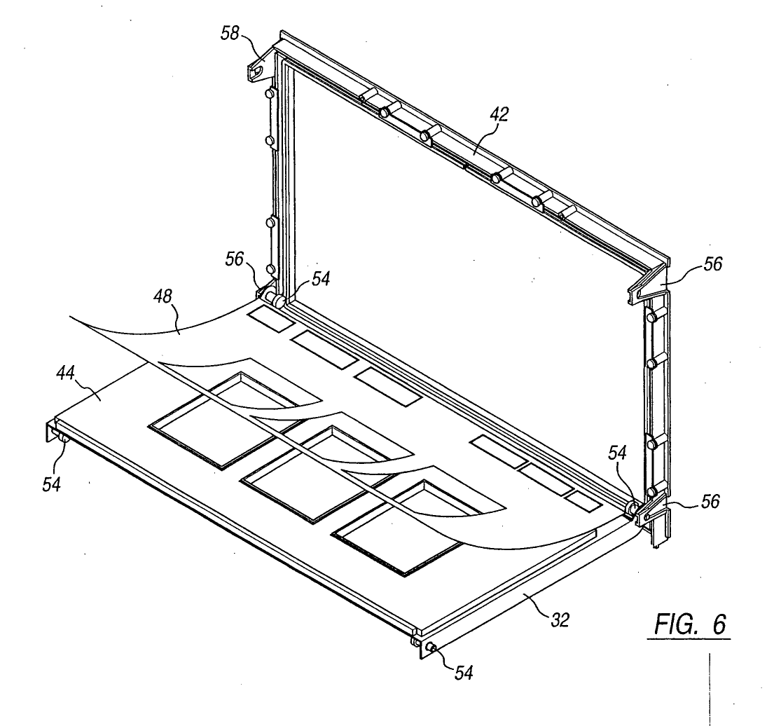

FIG. 5 shows an enlarged perspective view of the three main components in the Universal Reel Display System. The base panel 44 is constructed of a clear acrylic material to allow for the passage of varying colored light. It may also be constructed of polycarbonate, glass, or any other translucent material but is not limited to these materials. The mounting frame 32, the base panel 44, and the front display assembly 42 fit together via a pin mechanism shown in FIG. 6. Referring to FIG. 6, spring-loaded pins 54 secure the mounting frame 32 to the front display assembly 42. The display bezel 42 is fixed to the frame of the gaming machine using fasteners such as screws. The mounting frame 32, rectangular in shape but not limited to a particular shape, has four pins 54 located on the corners and extending from the sides of the mounting frame 32 in a horizontal manner. The pins 54 are inserted into holes in four flanges 56 on the front display assembly 42. The bottom two pins on the mounting frame 32 are secured to extended frame arms allowing the mounting frame 32 to be pivoted from the top. The pins on all four corners of the mounting frame 32 allow it to be removed entirely depending on service requirements or design factors such as a limitation of the direction that the mounting frame 32 can be pivoted. It should be recognized by those with ordinary skill in the art that the spring-loaded pins can be provided in a vertical manner allowing the mounting frame 32 to be pivoted from side to side should design requirements necessitate. FIG. 6 also shows the base panel 44 secured to the mounting frame 32. The variable artwork element 48 is a translucent flexible sheet with printed artwork supporting the theme of the game. The variable artwork element 48 is constructed of a film material and can be secured to the base panel 44 or the display glass 38 by adhesive or compression. FIG. 6 demonstrates the access method allowing reconfigurations of the lighting devices and replacement of the artwork element during game conversions.

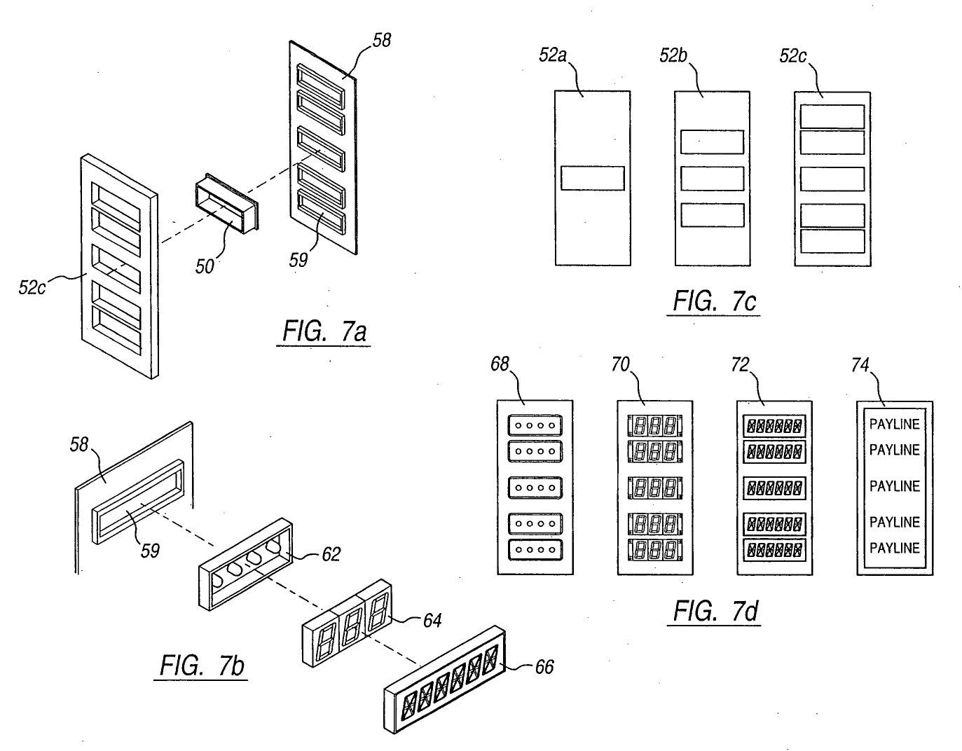

FIG. 7a shows the primary component, the printed circuit board (PCB) 58, of the pay line assembly on the Universal Reel Display System. PCB 58 has sockets 59 to which light components attach, are powered, and controlled. The common bezel 50 also conforms to a standard size for connecting to the PCB 58 and providing a finished appearance to the displays. The final aspect of the pay line assembly is the use of a 1-position insert 52a, 3-position insert 52b, or 5-position insert 52c (shown in FIG. 7c). FIG. 7a shows a 5-position insert 52c. FIG. 7b shows the three types of lighting components that can be attached to PCB 58 and used to identify certain pay line characteristics. They are LED display 62, 7-segment numeric display 64, and alphanumeric display 66. Each display adheres to the same form factor requirements for installation into the sockets 59 on the PCB 58. FIG. 7c shows the three types of pay line inserts presented in this embodiment. Like the base panel 44, the pay line inserts 52 are also constructed of a clear acrylic material to allow for the passage of varying colored light. They may also be constructed of polycarbonate, glass, or any other translucent material but are not limited to these materials and may actually be constructed of opaque materials such as colored plastic or sheet metal. While the PCB 58 is always constructed with a common number of sockets 59, the variability of the games using this system allow for any number of pay line lighting displays. To alter the number of pay line displays appearing, variable opening pay line panels are used. In this embodiment, a 1-position insert 52a, a 3-position insert 52b, or a 5-position insert 52c can be included in the design and manufacture of the gaming machine depending on the requirements of the game. It should be recognized by those with ordinary skill in the art that the number of PCB 58 sockets, pay lines, and lighting displays can vary depending on the requirements of the game design. FIG. 7d shows four examples of pay line assembly types. The 5-position examples include an LED pay line assembly 68, a 7-segment numeric pay line assembly 70, a 6-character alphanumeric pay line assembly 72, and an LCD assembly 74.

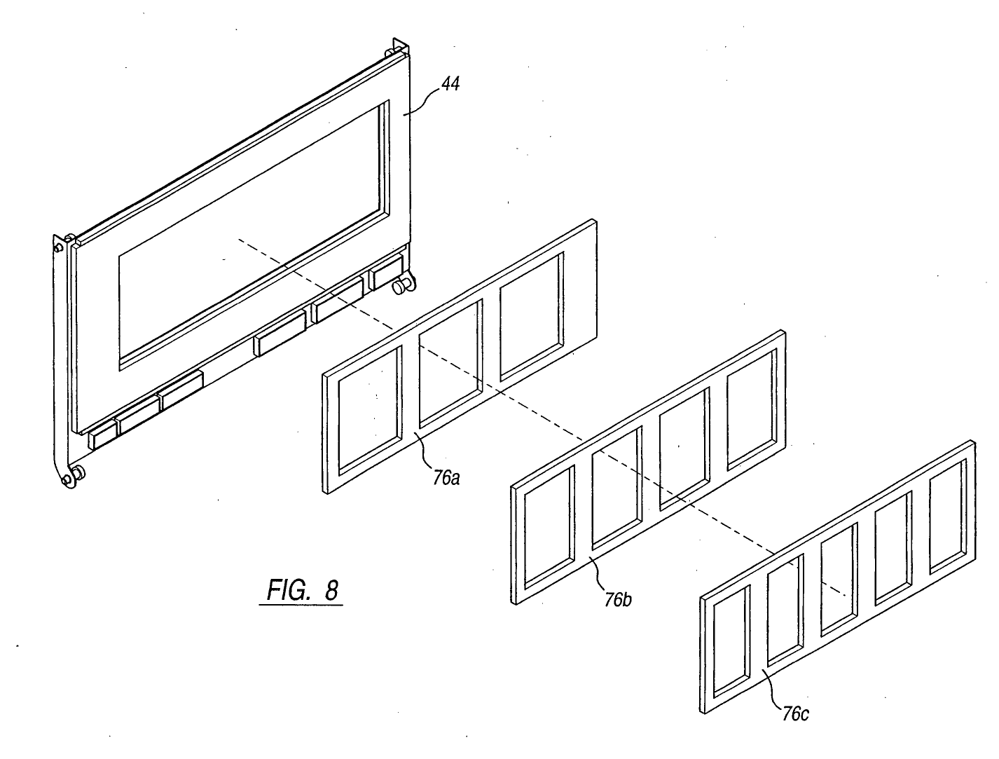

FIG. 8 shows the variation in reel inserts 76. In this example, 3-reel insert 76a, 4-reel insert 76b, and 5-reel insert 76c are interchangeable within the reel position on base panel 44. Like the base panel 44, the reel inserts 76 are also constructed of a clear acrylic material to allow for the passage of varying colored light. They may also be constructed of polycarbonate, glass, or any other translucent substance but are not limited to these materials and may actually be constructed of opaque materials such as colored plastic or sheet metal.

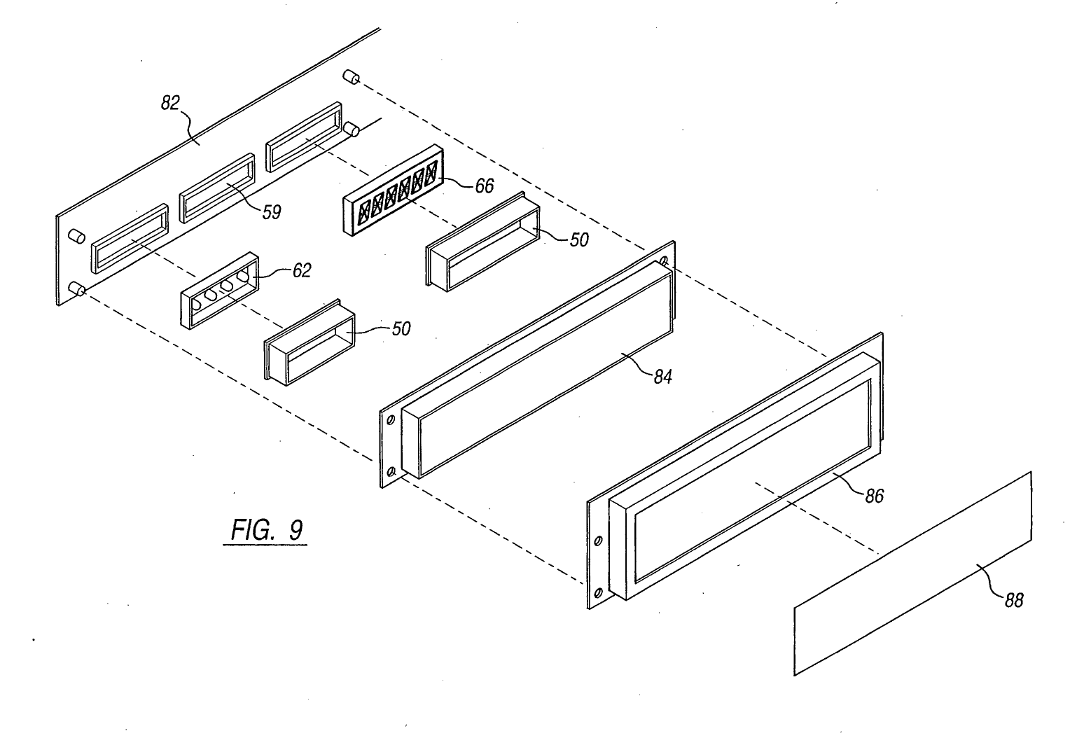

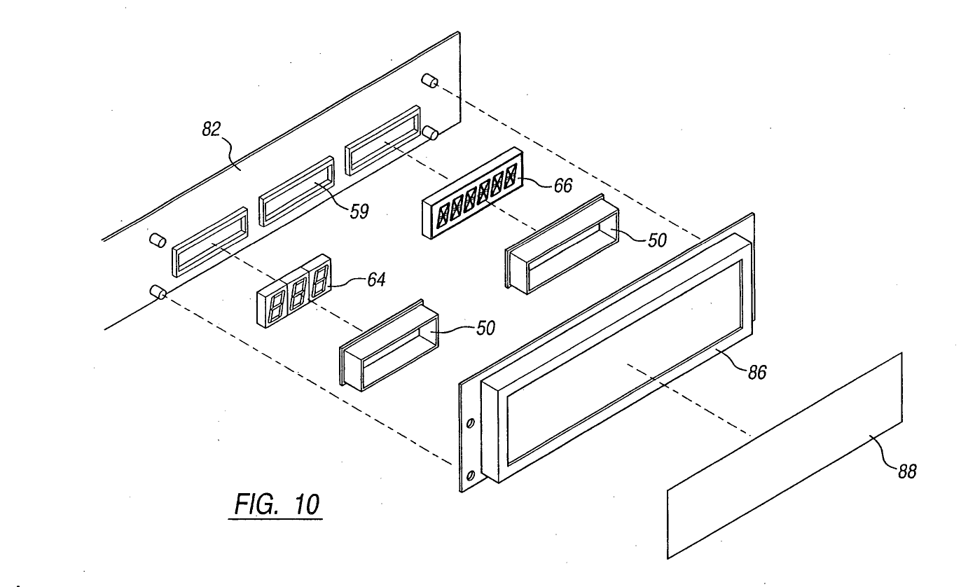

FIG. 9 is an exploded perspective view showing one-half of the control hub 82 located at the bottom of the Universal Reel Display System. Control hub 82 is a PCB with lighting sockets 59 allowing for the connection of common lighting displays depicted in FIG. 7. In this example, an LED display 62 and an alphanumeric display 66 are shown. Common bezel 50 is used to add a finished look to the lighting displays. Alternatively, an LCD 86 with or without a Dotmation screen 88, or a VFD 84, may be used in place of the light displays. FIG. 10 is an exploded perspective view showing the opposite half (from FIG. 9) of the control hub 82. In this example, 7-segment numeric display 64 and alphanumeric display 66 are shown. Common bezel 50 is used to add a finished look to the lighting modules. Alternatively, an LCD 86 with or without a Dotmation screen 88, or a VFD 84 (not shown), may be used in place of the light displays.

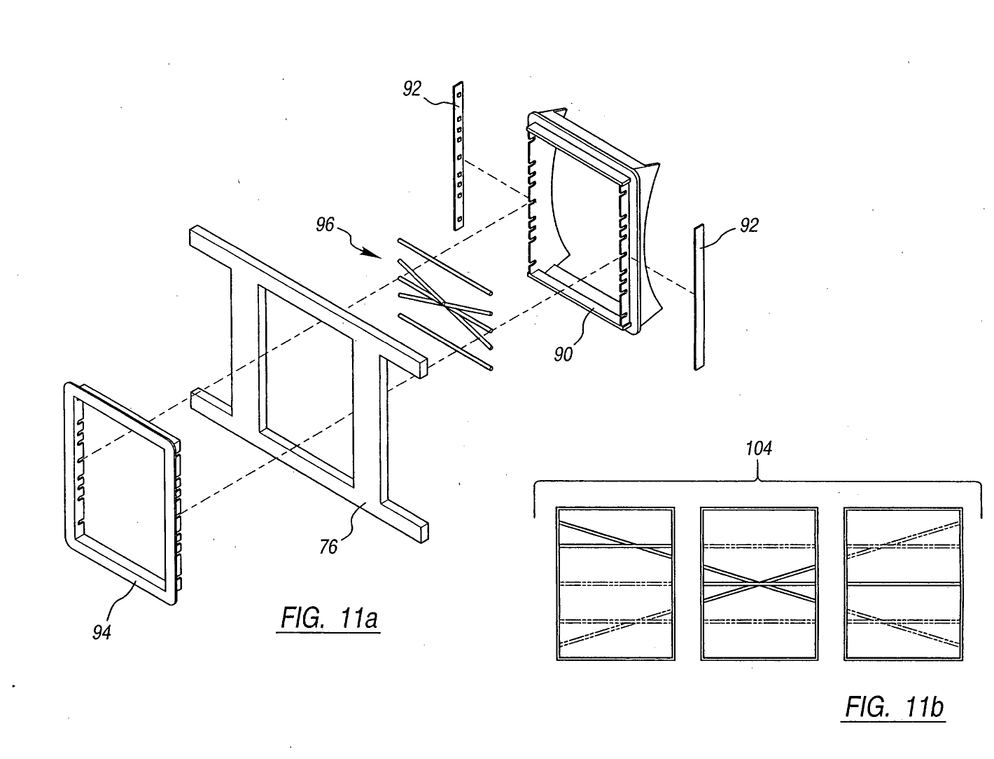

One embodiment of a reel pay line lighting assembly is shown in the exploded perspective view in FIG. 11a. Light pipe base 90 is used to position the light pipes 96 in a specified pay line order to identify winning outcomes by lighting specific pay lines. Two light pipe PCBs 92 are used to illuminate the light pipes 96 and provide light to the specified pay line light pipes as required by the game. The light pipe base 90 with light pipes 96 and light pipe PCBs 92 are positioned within a reel cutout on a reel insert 76. Light pipe bezel 94 is secured to the light pipe base 90 completing the assembly. FIG. 11b is a front view of an example pay line orientation using light pipes 96. In this example, a 3-reel display is shown but may be configured to support any number of reel displays required by the game.

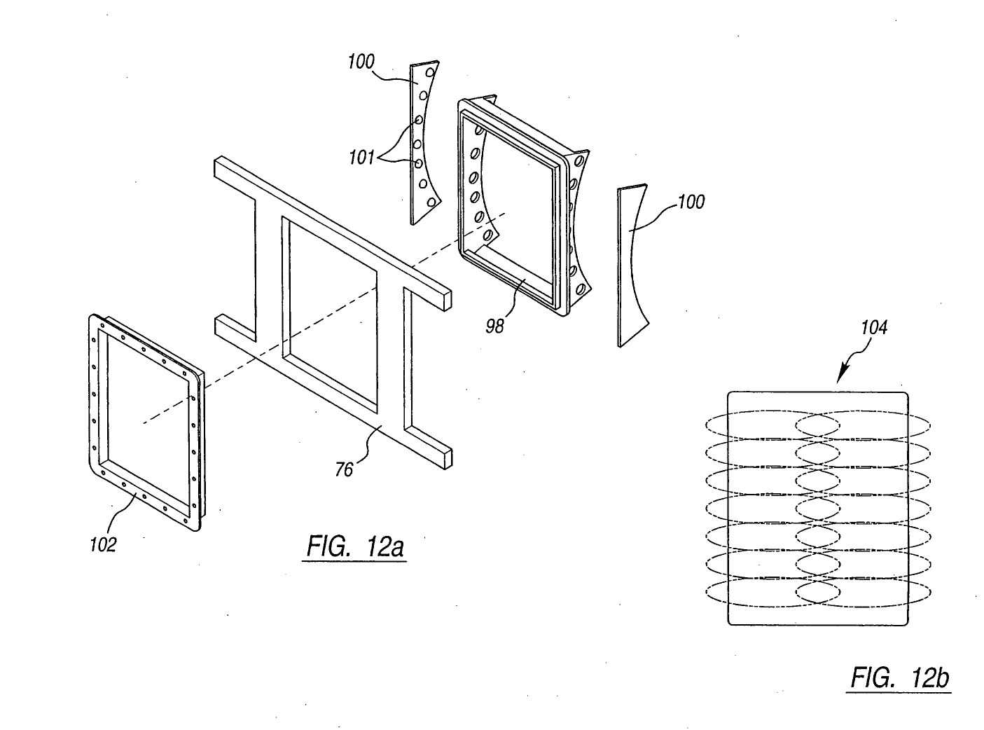

FIG. 12a is an exploded perspective view presenting another example of a reel pay line lighting assembly. LED base 98 is used to position and secure two LED PCBs 100 containing a number of LEDs 101. The LEDs 101 are positioned to supply lighting to the reels and can be configured to provide lighting to specified pay lines required by the game. LED base 98 with LED hubs 100 are positioned within a reel cutout on a reel insert 76. LED bezel 102 is positioned on the opposite side of the reel insert 76 and secured to LED base 98 through the reel cutout. FIG. 12b is a front view of an example pay line lighting pattern 104 using the LED reel pay line lighting assembly is also presented. In this example, an individual reel is shown with seven lighting segments available depending on the pay line requirements of the game.

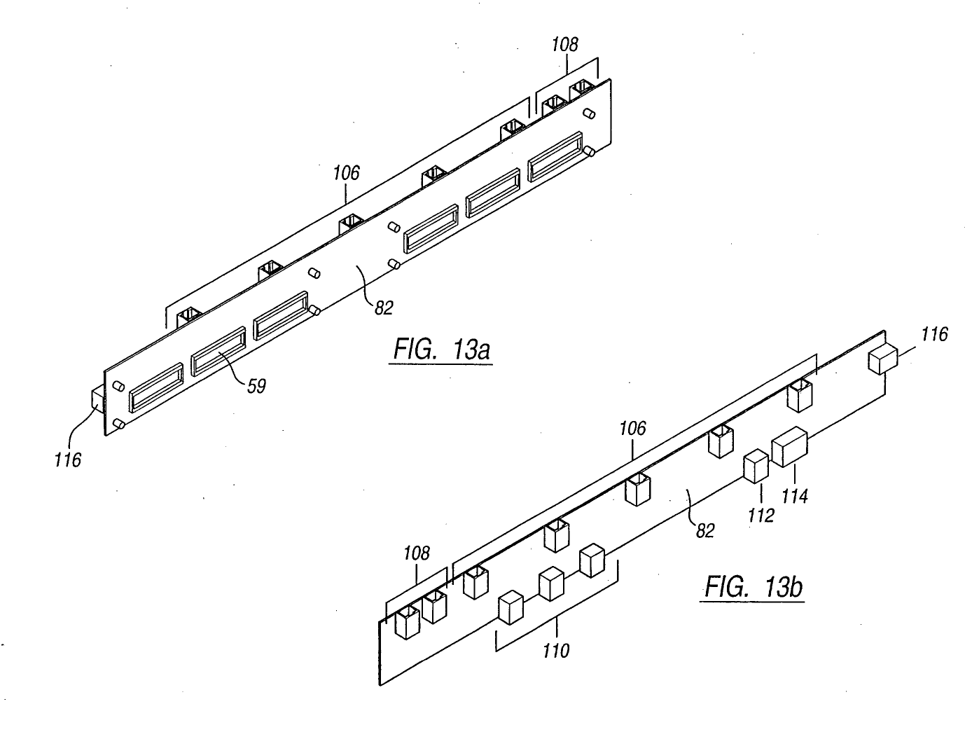

Control hub 82 is depicted in FIG. 13a (front) and 13b (rear) showing sockets 59 for connecting lighting displays and a variety of connector sockets for wiring to provide power and signaling to all modules and lighting components on the Universal Reel Display System. Five reel-position connector sockets 106 are used to connect wiring or wiring harnesses to provide power and send signals to the pay line lighting assemblies shown in FIGS. 11a and 12a. The wiring may also provide power to lighting on or around the reels. Alternate display connector sockets 108 are used to connect wiring to other displays that may be present in a particular gaming machine. Lower display connector sockets 110 connect wiring to and from the lighting modules, displays, and buttons below the main reel display. Signal connector socket 112 connects to wiring for transmitting and receiving signals from the main processor and other controllers. Main power connector socket 114 connects to wiring or cabling providing the main power to the control hub 82. Pay line connector socket 116 connects to wiring that provides power and signaling to the pay line lighting modules shown in FIG. 7.

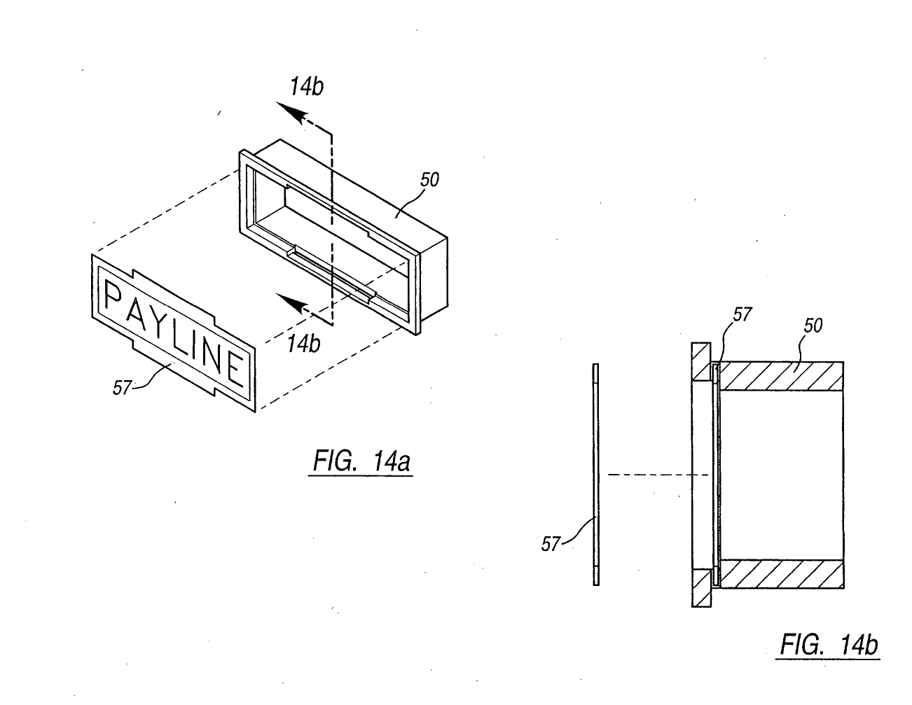

FIG. 14a is a perspective view and FIG. 14b is a side view, taken generally along the line 14b-14b in FIG. 14a, of the common bezel 50 and the translucent insert 57. The translucent insert 57 may be constructed with lettering that is clearly visible when backlighting is used to illuminate this lighting module. The side view shown in FIG. 14b shows how the translucent insert 57 is placed in the common bezel 50 in its final position.

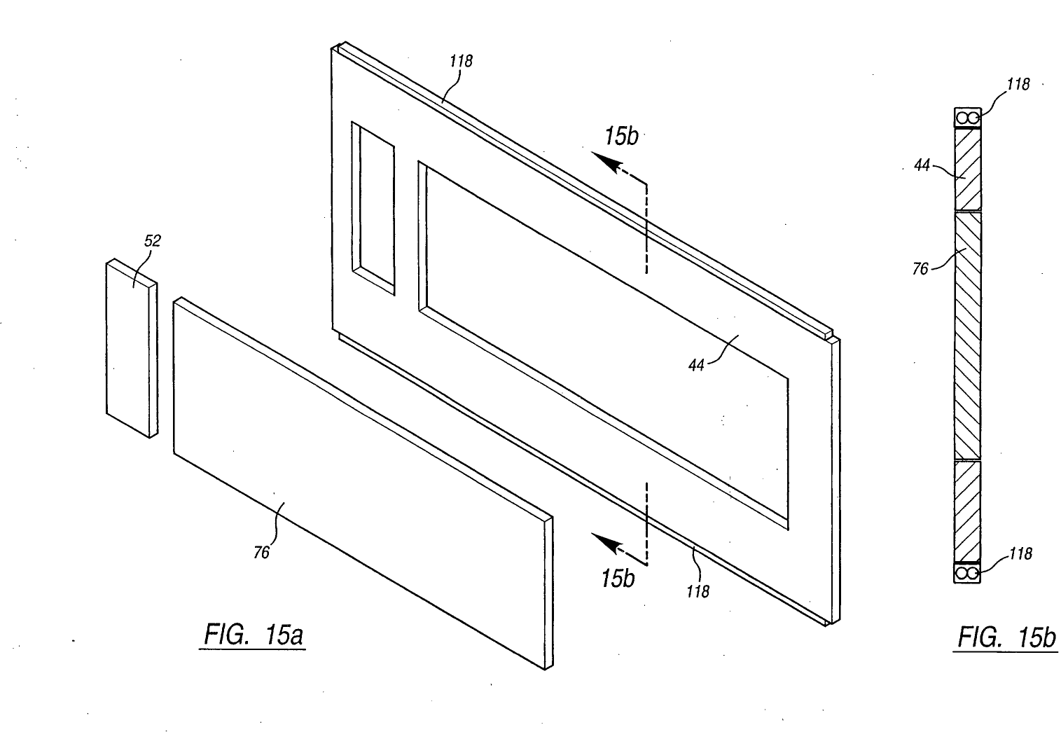

FIG. 15b is a perspective and FIG. 15b is a side view, taken generally along the line 15b-15b in FIG. 15a, showing the relationship and lighting technique used to illuminate the entire surface or selected portions of the surface of the base panel 44. In this embodiment, small form factor fluorescent bulbs 118 are used to provide the illumination. Other lighting devices may also be used such as LEDs, incandescent, and others as the design requires or permits. The base panel 44, the reel insert 76, and the pay line insert 52 are constructed of a translucent material such as acrylic. Other material with the same translucent properties may also be used. The side view shown on FIG. 15 shows the relationship of the inserted components to the base panel 44. Reel insert 76 and pay line insert 52 are placed in such proximity to the base panel 44 that light traveling through base panel 44 also passes through reel insert 76 and pay line insert 52 though not depicted in the side view in FIG. 15. In most applications, the reel light panel 76 and pay line panel 52 will be constructed of the same material as the base panel 44 so as to appear as if the entire panel is one piece.

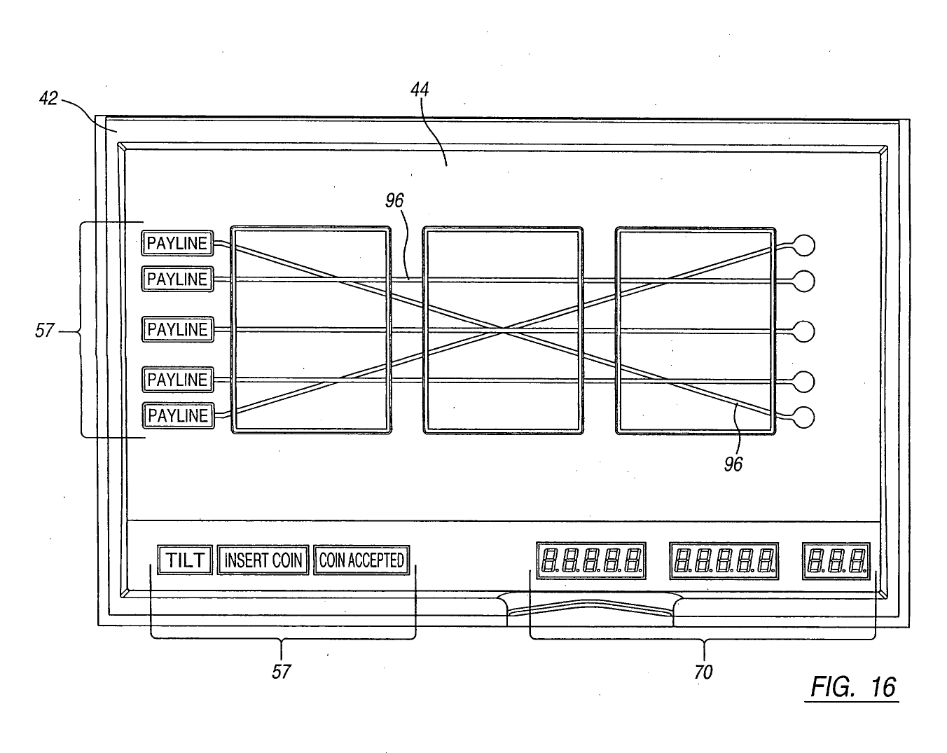

FIG. 16 is a front view of an example Universal Reel Display in its finished form. In this example, front display assembly 42 is the outermost component protecting the internal components of the gaming machine's reel display area. Base panel 44 is the main surface area for the display. Pay line inserts 57 are shown as the main pay line display. Light pipes 96 are used to define the pay lines across the reels. Inserts 57 are used at the bottom of the display area to provide additional information to the player. 7-segment numeric displays are used in the lower right portion of the display area to provide numeric information to the player such as credit accumulation, bet per line, and other game-related numbers.

While the present invention has been described with reference to one or more particular embodiments, those skilled in the art will recognize that many changes may be made thereto without departing from the spirit and scope of the present invention.

For example, a transmissive LCD panel can replace the display components providing the entire communication presentation to players and technicians while allow a clear view to the reels on the opposite side of the display. Individual LED, LCD, and VFD meters can be used instead of the lighting displays for the pay line assemblies.

Each of these embodiments and obvious variations thereof is contemplated as falling within the spirit and scope of the claimed invention, which is set forth in the following claims.

1. A modular reel display system for a gaming machine, comprising:
a display unit for revealing a plurality of reels; and
a removable pay line module in proximity to the display unit and indicating a number of playable pay lines.

2. The system of claim 1, wherein the pay line module includes a removable pay line insert within the display unit.

3. The system of claim 2, wherein the pay line module includes a printed circuit board removably coupled to the pay line insert.

4. The system of claim 3, wherein the pay line module includes at least one display removably coupled to the printed circuit board.

5. (canceled)

6. The system of claim 2, wherein the pay line insert is composed of a light transmitting material.

7. The system of claim 1, wherein the display unit includes a base member and a removable reel window insert within the base member, the reel window insert including a plurality of windows for revealing the plurality of reels.

8. (canceled)

9. (canceled)

10. The system of claim 1, further including an information module adjacent to the display unit, the information module communicating information to the player, the information being selected from a group consisting of one or more of game state, credits in, lines bet, bet per line, total bet, and credits won.

11. (canceled)

12. (canceled)

13. The system of claim 1, further including a mounting frame, the display unit being mounted to the mounting frame.

14. (canceled)

15. A method of manufacturing a modular reel display system for a gaming machine, the method comprising:
providing a display unit for revealing a plurality of reels; and
providing a removable pay line module in proximity to the display unit, the pay line module indicating a number of playable pay lines.

16. The method of claim 15, wherein the pay line module includes a removable pay line insert within the display unit.

17. The method of claim 16, wherein the pay line module includes a printed circuit board removably coupled to the pay line insert.

18. The method of claim 17, wherein the pay line module includes at least one display removably coupled to the printed circuit board.

19. (canceled)

20. The method of claim 16, wherein the pay line insert is composed of a light transmitting material.

21. The method of claim 15, wherein the display unit includes a base member and a removable reel window insert within the base member, the reel window insert including a plurality of windows for revealing the plurality of reels.

22. (canceled)

23. (canceled)

24. The method of claim 15, further including providing an information module adjacent to the display unit, the information module communicating information to the player, the information being selected from a group consisting of one or more of game state, credits in, lines bet, bet per line, total bet, and credits won.

25. (canceled)

26. (canceled)

27. The method of claim 15, further including mounting the display unit to a mounting frame.

28. (canceled)

29. A method of converting a modular reel display system for a gaming machine, comprising:
providing a display unit for revealing a plurality of reels;
providing a first pay line module in proximity to the display unit, the first pay line module indicating a first number of playable pay lines;
removing the first pay line module from the system; and
providing a second pay line module in proximity to the display unit in place of the first pay line module, the second pay line module indicating a second number of playable pay lines, the second number being different from the first number.

30. The method of claim 29, wherein the first pay line module includes a removable first pay line insert, and wherein providing the first pay line module includes providing the first pay line insert within the display unit, wherein the second pay line module includes a removable second pay line insert, and wherein providing the second pay line module includes providing the second pay line insert within the display unit.

31. (canceled)

32. The method of claim 29, wherein the display unit includes a base member and a removable first reel window insert within the base member, further including removing the first reel window insert from the base member and providing a second reel window insert within the base member, the first reel window insert including a first number of windows for revealing the plurality of reels, the second reel window insert including a second number of windows different from the first number of windows.

33. (canceled)

34. The method of claim 29, further including providing an information module adjacent to the display unit, the information module communicating information to the player, the information selected from a group consisting of one or more of game state, credits in, lines bet, bet per line, total bet, and credits won.

35. (canceled)

36. (canceled)

37. (canceled)

38. (canceled)

39. (canceled)

40. (canceled)

41. (canceled)

42. (canceled)
